(19) United States
(12) Patent Application Publication
(10) Pub. No.: US 2024/0038911 A1
(43) Pub. Date: Feb. 1, 2024

(54) FLIP-CHIP SOLAR CELL

(71) Applicant: Sierra Space Corporation, Broomfield, CO (US)

(72) Inventors: Michael Bergmann, Broomfield, CO (US); Brian Anthony, Broomfield, CO (US); Matthew Johnson, Broomfield, CO (US)

(21) Appl. No.: 18/359,482

(22) Filed: Jul. 26, 2023

Related U.S. Application Data
(60) Provisional application No. 63/393,691, filed on Jul. 29, 2022.

(51) Int. Cl. H01L 31/0224; H01L 31/0687; H01L 31/048; H01L 31/0216

(52) U.S. Cl. CPC H01L 31/022458; H01L 31/0687; H01L 31/0481; H01L 31/02168

(57) ABSTRACT

Methods, devices, and systems are described for a flip-chip solar cell. The flip-chip solar cell includes a plurality of semiconductor layers having a first side and a second side. The plurality of semiconductor layers are configured to convert solar radiation to electrical energy. The flip-chip solar cell includes a coverglass layer coupled to the second side via a bond. The coverglass layer is configured to pass the solar radiation to the plurality of semiconductor layers and provide structural support for the plurality of semiconductor layers flip-chip solar cell. The flip-chip solar cell includes a first electrode pad and a second electrode pad coupled to the first side and electrically coupled to the plurality of semiconductor layers. The coverglass layer is thicker than the plurality of semiconductor layers. No metal layer is interposed between the plurality of semiconductor layers and the coverglass layer.

### CROSS-REFERENCE TO RELATED APPLICATIONS

This application claims priority to U.S. Provisional Application No. 63/393,691 entitled “FLIP-CHIP SOLAR CELL” and filed on Jul. 29, 2022, the disclosure of which is incorporated herein by reference in its entirety.

### TECHNICAL FIELD

The present disclosure relates generally to energy conversion, and more particularly, to a flip-chip solar cell.

### BACKGROUND

Solar power generation systems use the photovoltaic effect to convert solar radiation into electrical power. The photovoltaic effect can be accomplished by a multi-junction solar cell having multiple bandgaps. Multi-junction solar cell converts the solar radiation into electrical power by utilizing a III-V semiconductor with an appropriate bandgap. Solar radiation with a higher energy than the bandgap excites electron-hole pairs in the multi-junction solar cell to generate electricity for an external electrical system. Also, multi-junction solar cells are fabricated by depositing III-V semiconductors on a substrate that has approximately the same lattice constant as the substrate.

But multi-junction solar cells have several drawbacks. In comparison to less efficient silicon substrates, the substrates for multi-junction solar cells are expensive and the manufacturing process is complex. This makes multi-junction solar cells expensive and tedious to manufacture due to the higher substrate costs and intricate manufacturing process. Additionally, substrates for multi-junction solar cells are twice as dense as silicon and, therefore, are much heavier than silicon-based substrates. This additional weight presents challenges for flight applications (e.g., satellites and solar-powered aerial vehicles) where specific power (i.e., the amount of power generated per unit weight of the structure) is an important metric. Thus, in order to meet the demand for inexpensive, low-weight, and highly efficient solar-cell technology, improved structures and methods for fabricating multi-junction solar cells are needed.

### SUMMARY

The present disclosure relates generally to the fields of energy conversion, including systems and methods useful for a flip-chip solar cell.

In one aspect, disclosed herein is a flip-chip solar cell. The flip-chip solar cell includes a plurality of semiconductor layers having a first side and a second side. The plurality of semiconductor layers is configured to convert solar radiation to electrical energy. The flip-chip solar cell includes a coverglass layer coupled to the second side via a bond. The coverglass layer is configured to pass the solar radiation to the plurality of semiconductor layers and provide structural support for the plurality of semiconductor layers. The flip-chip solar cell includes a first electrode pad and a second electrode pad coupled to the first side and electrically coupled to the plurality of semiconductor layers. The coverglass layer is thicker than the plurality of semiconductor layers in most embodiments. No metal layer is interposed between the plurality of semiconductor layers and the coverglass layer.

In some variations, the plurality of semiconductor layers includes sub-cells including at least first sub-cell, a second sub-cell, and a third sub-cell, the first sub-cell having a first energy bandgap, the second sub-cell having a second energy bandgap, and the third sub-cell having a third energy bandgap, the first energy bandgap being greater than the second energy bandgap and the third energy bandgap. Further, the plurality of semiconductor layers includes at least one of Ge, In, Al, Ga, As, P, N, Si, or Sb. Additionally, the first sub-cell is electrically coupled to at least one of the first electrode pad or the second electrode pad by a set of contact vias that partially pass through the first sub-cell, the set of contact vias terminating with an ohmic metallization within the first sub-cell.

In some variations, the first sub-cell is electrically coupled to at least one of the first electrode pad or the second electrode pad by a set of through vias that pass through the first sub-cell, the set of through vias being coupled to a transparent conductive layer interposed between the plurality of semiconductor layers and the coverglass layer. Further, the transparent conductive layer is deposited on the second side of the plurality of semiconductor layers. Additionally, the dielectric layer includes a first dielectric layer portion coupled to the second side of the plurality of semiconductor layers and a second dielectric layer portion coupled to the coverglass layer, and wherein the bond between the second side of the plurality of semiconductor layers and the coverglass layer is formed by the force applied to the first dielectric layer portion and the second dielectric layer portion interposed between the second side of the plurality of semiconductor layers and the coverglass layer.

In some variations, the coverglass layer is less than 200 μm thick. Further, the coverglass layer includes sapphire. Additionally, the surface-mountable solar cell includes a contact metal layer extending across the first side of the plurality of semiconductor layers, the contact metal layer configured to electrically couple to at least one of the first electrode pad or the second electrode pad. Further, the surface-mountable solar cell has a mass per area is <0.1 g/cm³.

In some variations, the surface-mountable solar cell includes an anti-reflective layer interposed between the plurality of semiconductor layers and the coverglass layer, the anti-reflective layer configured to minimize reflection between the plurality of semiconductor layers and the coverglass layer. Further, the anti-reflective layer includes a stack of dielectric layers and wherein the anti-reflective layer is further configured to reduce reflection of incident light passing through the coverglass layer. Additionally, an anti-reflective layer is deposited on the coverglass layer, the anti-reflective layer configured to minimize reflection at the coverglass layer. In some variations, the anti-reflective layer includes a stack of dielectric layers and wherein the anti-reflective layer is further configured to reduce reflection at a surface of the coverglass layer.

In another aspect, disclosed herein is a flip-chip solar cell configured to power a non-terrestrial application device coupled to the surface-mountable solar cell. The flip-chip solar cell includes a plurality of semiconductor layers having a first side and a second side. The plurality of semiconductor layers is configured to convert solar radiation to electrical energy. The flip-chip solar cell includes a coverglass layer coupled to the second side via a bond. The coverglass layer is configured to pass the solar radiation to the plurality of semiconductor layers and provide structural support for the plurality of semiconductor layers. The flip-chip solar cell includes a first electrode pad and a second electrode pad coupled to the first side and electrically coupled to the plurality of semiconductor layers. The coverglass layer is thicker than the plurality of semiconductor layers in most embodiments. No metal layer is interposed between the plurality of semiconductor layers and the coverglass layer.

In some variations, the surface-mountable solar cell forms an array with a second surface-mountable solar cell, and wherein a first edge of the surface-mountable solar cell is within 0.5 mm of a second edge of the second surface-mountable solar cell. Further, the surface-mountable solar cell and the second surface-mountable solar cell cover more than 75% of a module surface area of the non-terrestrial application device.

In yet another aspect, disclosed herein is a flip-chip solar cell that includes a semiconductor layer having a first doped region at a first side of the semiconductor layer and a second doped region at a second side of the semiconductor layer. The first side opposing the second side, the semiconductor layer configured to convert solar radiation to electrical energy, the second side configured to face the solar radiation. The flip-chip solar cell includes a coverglass layer coupled to the second side via a bond and is configured to pass the solar radiation to the semiconductor layer and provide structural support for the semiconductor layer. The flip-chip solar cell includes a first electrode pad and a second electrode pad coupled to the first side and electrically coupled to the semiconductor layer. No metal layer is interposed between the plurality of semiconductor layers and the coverglass layer.

### BRIEF DESCRIPTION OF THE DRAWINGS

The embodiments herein may be better understood by referring to the following description in conjunction with the accompanying drawings in which like reference numerals indicate identically or functionally similar elements, of which:

FIG. 1A depicts an example of an epitaxial layer deposited on a germanium substrate;

FIG. 1B depicts an example of a triple junction cell semiconductor layer structure including the three sub-cells that are connected by two tunnel junctions;

FIG. 2 depicts an example of a sapphire layer directly bonded to the epitaxial layer grown on the germanium substrate;

FIG. 3A depicts an example of the fabricated flip-chip solar cell bonded to a printed circuit board;

FIG. 3B depicts a bottom view of the flip-chip solar cell including a p-electrode pad and the n-electrode pad;

FIG. 4 depicts an example of a cross-section of a fabricated flip-chip solar cell having a contact via to expose the top sub-cell;

FIG. 5A depicts an example of a cross-section of a partially fabricated flip-chip solar cell with a via-opening photoresist layer deposited on the p-contact metal for creating an etch for the contact via to expose the top sub-cell;

FIG. 5B depicts an example of a cross-section of a partially fabricated flip-chip solar cell with an etch for the contact via that passes through the third sub-cell, the second sub-cell, and partially passes through the first sub-cell;

FIG. 5C depicts an example of a cross-section of a partially fabricated flip-chip solar cell with a passivation deposition and a via-opening photoresist layer for creating an etch through the passivation layer to expose the p-contact metal and the top sub-cell;

FIG. 5D depicts an example of a cross-section of a partially fabricated flip-chip solar cell with a liftoff resist layer for creating the n-electrode pad and the p-electrode pad;

FIG. 5E depicts an example of a cross-section of a partially fabricated flip-chip solar cell with a metal contact deposition and an electrode pad deposition formed over the two etches and the liftoff photoresist layer;

FIG. 5F depicts an example of a cross-section of a partially fabricated flip-chip solar cell of an n-electrode pad and a p-electrode pad that are formed by a lift-off of the photoresist layer;

FIG. 6 depicts an example of a transparent conductive layer deposited on an epitaxial layer with a germanium substrate;

FIG. 7 depicts an example of a cross-section of a fabricated flip-chip solar cell having a through-via to a transparent conductive layer;

FIG. 8A depicts an example of a cross-section of a partially fabricated flip-chip solar cell with a p-metal contact deposited on the epitaxial layer and an etch at the edge of the solar cell passing through the transparent conductive layer and the oxide bonding layer;

FIG. 8B depicts an example of a cross-section of a partially fabricated flip-chip solar cell with an etch for the through-via that passes through the third sub-cell, the second sub-cell, and the first sub-cell layer to expose the transparent conductive layer;

FIG. 9 depicts an example of a cross-section of a fabricated flip-chip solar cell with a doped n-region and a doped p-region;

FIG. 10A depicts a diagram of a commercial metal-wrap-through solar cell;

FIG. 10B depicts a proposed solar cell diagram of the layer thicknesses of the fabricated solar cell with the thinned-down germanium layer and the thinned-down sapphire layer for weight reduction;

FIG. 10C depicts a solar cell comparison table comparing the thickness and density of the proposed flip-chip solar cell to the current flip-chip solar cell;

FIG. 11 depicts a flip-chip solar cell fabrication flowchart for bonding a sapphire layer to an epitaxial layer with a germanium substrate;

FIG. 12 depicts a block diagram of the flip-chip solar cell coupled to a non-terrestrial application device;

FIG. 13A depicts a top-view of an example of a transparent conductive layer having finger contacts;

FIG. 13B depicts a cross-section of an example of a transparent conductive layer having finger contacts deposited on active layers of a GaInP/GaInAs/Ge triple-junction cell; and

FIG. 13C depicts an example of a cross-section of a fabricated solar cell having a finger contact of a transparent conductive layer.

### DETAILED DESCRIPTION

The methods, systems, and apparatuses described herein are for a flip-chip solar cell. In the following detailed description, reference is made to the accompanying drawings, which form a part hereof. In the drawings, similar symbols generally identify similar components, unless context dictates otherwise. The illustrative alternatives described in the detailed description, drawings, and claims are not meant to be limiting. Other alternatives may be used and other changes may be made without departing from the spirit or scope of the subject matter presented here. It will be readily understood that the aspects, as generally described herein, and illustrated in the Figures, can be arranged, substituted, combined, and designed in a wide variety of different configurations, all of which are explicitly contemplated and make part of this application.

Distributed electrical power conversion is becoming increasingly important. Common challenges for conventional power conversion and distributed electricity generation include efficiency, noise, and maintenance demands. Solar cells are uniquely positioned to address many of these demands due to their scalable efficiency, few moving parts, and near silent operation.

The flip-chip solar cell described herein converts solar radiation to electrical power with a high quantum efficiency and reduces spectral losses of received solar radiation. Spectral loss may also occur due to low-energy photons not being absorbed by the solar cell. Low energy photons may include photons having an energy level less than the bandgap of the solar cell. Spectral losses may also occur due to band edge relaxation of charge carriers generated by photons with energy greater than the bandgap of photovoltaic cells.

Multi-junction solar cells convert solar radiation into electrical power by utilizing III-V semiconductors with an appropriate bandgap. But drawbacks of multi-junction solar cells include expensive substrates and a complex manufacturing process. Multi-junction solar cells are composed of epitaxial layers including III-V semiconductors that may be deposited on germanium (Ge) substrates. Germanium substrates are expensive compared to silicon substrates. Additionally, growing epitaxial layers on the germanium substrate involves a complicated manufacturing process. The multi-junction solar cells must have approximately the same lattice constant as the lattice constant of the substrate. Otherwise, growing mismatched epitaxial layers on a substrate having a different lattice constant may cause strains and defects during the epitaxial growth. Furthermore, complex fabrication processes may be required after epitaxial-layer depositions to make electrical contact to the active device layers in order to form a functional solar cell. As such, a high-quality multi-junction solar cell requires expensive tools and a precise manufacturing process.

A drawback of multi-junction solar cells grown on germanium substrates is the relatively high density of germanium. Germanium substrates used for epitaxial growth add extra weight to the multi-junction solar cell. This extra weight presents challenges for flight applications (e.g., satellites and solar-powered aerial vehicles) where specific power (i.e., the amount of power generated per unit weight of the structure) is an important metric. But removing or thinning may cause the multi-junction solar cell to crack. Cracks in the solar cell compromise the functionality of the multi-junction solar cell. Thinning the germanium substrate to reduce weight without reinforcing the multi-junction solar cell can lead to a complete loss of functionality

The concepts described herein solve the drawbacks of multi-junction solar cells by improving the strength of the multi-junction solar cell while reducing the substrate weight and manufacturing complexity. For example, the epitaxial layers of the multi-junction solar cell may be bonded to a coverglass layer (e.g., sapphire coverglass layer) to enhance the strength of the multi-junction solar cell while maximizing transmission of solar radiation to the solar cell. The germanium substrate may be thinned or removed for reuse on other solar cells. Compared to other materials such as silicon, a coverglass layer of sapphire maintains a strong structural compatibility with germanium as temperature increases. Unlike silicon, sapphire has a coefficient of thermal expansion closer to germanium than silicon. Additionally, sapphire may provide a very high relative transmission of radiation compared to other materials, such as some glasses.

The flip-chip solar cell may include an epitaxial layer having a first side and a second side. The epitaxial layer is configured to convert solar radiation to electrical energy. The flip-chip solar cell includes a coverglass layer coupled to the second side via a bond. The coverglass layer is configured to pass the solar radiation to the epitaxial layer and provide structural support for the epitaxial layer. The flip-chip solar cell includes a first electrode pad and a second electrode pad coupled to the first side and electrically coupled to the plurality of semiconductor layers. The coverglass layer is thicker than the plurality of semiconductor layers. No metal layer is interposed between the epitaxial layer and the coverglass layer.

Bonding sapphire to a multi-junction solar cell may include forming an epitaxial layer on a substrate. Forming the flip-chip solar cell may include disposing a first dielectric layer on the second side of the epitaxial layer. Forming the flip-chip solar cell may include disposing a second dielectric layer over a coverglass layer. Forming the flip-chip solar cell may include arranging the second dielectric layer over the first dielectric layer such that the coverglass layer and the epitaxial layer are positioned on opposing sides of the first dielectric layer and the second dielectric layer. Forming the flip-chip solar cell may include fusing the first dielectric layer to the second dielectric layer via a transparent bond.

The transparent bond may include joining the first dielectric layer and the second dielectric layer via a covalent bond without an adhesive. Forming the flip-chip solar cell may include applying a post-bond annealing step to strengthen the covalent bond between the first dielectric layer and the second dielectric layer. Forming the flip-chip solar cell may include thinning the substrate to a thickness in a range of approximately 10-30 m. Forming the flip-chip solar cell may include thinning the sapphire layer to a sapphire layer thickness in a range of approximately 100-200 μm.

The manufacturing process may include growing the epitaxial layers on the substrate and then bonding the multi-junction solar cell to sapphire. The manufacturing process may remove the substrate to increase efficiency and reduce costs by using the removed portion of the substrate to regrow other epitaxial layers.

The flip-chip solar cell may be manufactured using one of two fabrication processes. The first fabrication method may include forming a contact via or a via stopping at the first sub-cell. The contact via does not have a through-via passing through all the epitaxial layers. Rather, the first fabrication method includes the via stopping at the first sub-cell to electrically connect the first sub-cell to the n-electrode pad. The second fabrication method may include forming a transparent conductive layer between the epitaxial layer and the coverglass layer. The transparent conductive layer may be an indium tin oxide layer or an indium zinc oxide layer over the first sub-cell (possibly over an AlInP layer that acts as a window layer over the InGaP active layers). Additionally, the second fabrication method may include forming a through-via that passes through the entire epitaxial layer to expose the transparent conductive layer and to electrically connect the transparent conductive layer to the n-electrode pad.

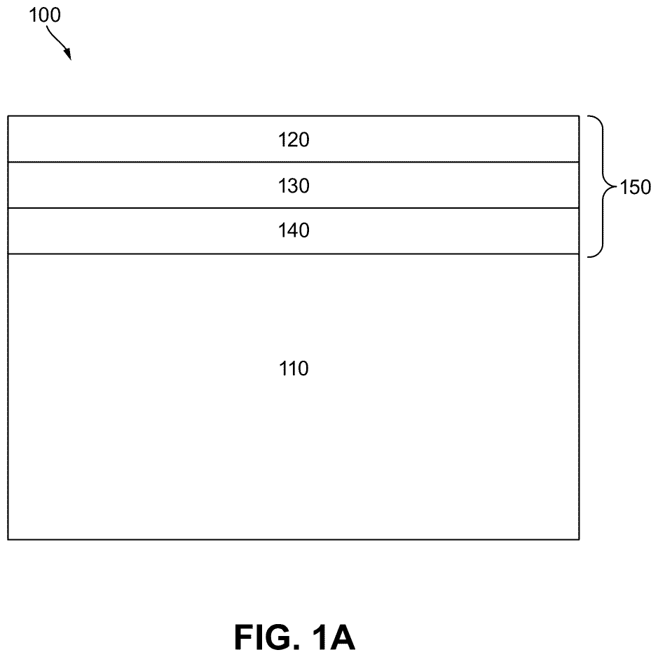

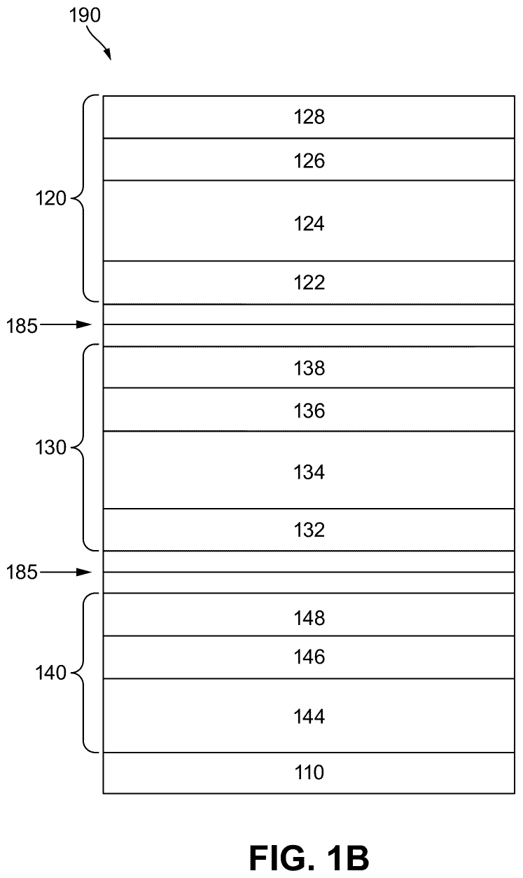

Referring to FIG. 1A, illustrated is an example of active layers 150 deposited on a germanium substrate 110. The active layers 150 may be a photovoltaic cell configured to convert solar radiation to electrical power. The active layers 150 may include a p-n junction solar cell having a P-doped layer and an N-doped layer. The active layers 150 may include a multi-junction solar cell 100 including two or more cells. In some embodiments, the active layers 150 may be a multi-junction solar cell 100 including three cells: a first sub-cell 120, a second sub-cell 130, and a third sub-cell 140. The three cells may be grown on a germanium substrate 110. The active layers 150 may be a plurality of semiconductor layers.

The third sub-cell 140 may be formed from the germanium substrate 110 through a diffusion process. The third sub-cell 140 may have a bandgap energy in the range of approximately 0.6 eV to approximately 0.75 eV. In some embodiments, the third sub-cell 140 may have a bandgap energy of approximately 0.67 eV. The third sub-cell 140 may include at least one of Al, Ge, In, Al, Ga, As, P, N, Si, or Sb.

The second sub-cell 130 may be deposited on the third sub-cell 140. The second sub-cell 130 may include GaAs or InGaAs to match the lattice constant of the third sub-cell 140. The second sub-cell 130 may have a bandgap energy in the range of approximately 1.3 eV to approximately 1.55 eV. In some embodiments, the second sub-cell 130 may have a bandgap energy of approximately 1.42 eV. The second sub-cell 130 may include at least one of Al, Ge, In, Al, Ga, As, P, N, Si, or Sb. The energy bandgap of the second sub-cell 130 may be greater than the energy bandgap of the third sub-cell 140.

The first sub-cell 120 may be deposited on the second sub-cell 130. The first sub-cell 120 may include InGaP to match the lattice constant of the second sub-cell 130. The first sub-cell 120 may have a bandgap energy in the range of approximately 1.65 eV to approximately 2.0 eV. In some embodiments, the first sub-cell 120 may have a bandgap energy of approximately 1.85 eV. The first sub-cell 120 of the active layers 150 may be configured to face the solar radiation. In some embodiments, the first sub-cell may have a window layer grown above it with a bandgap energy larger than the active layers composed of InGaP. The window layer may be AlInP. In some embodiments, the first sub-cell may include at least one of Al, Ge, In, Al, Ga, As, P, N, Si, or Sb. The energy bandgap of the first sub-cell 120 may be greater than the energy bandgap of the second sub-cell 130.

Referring to FIG. 1B, illustrated is an example of a triple junction cell semiconductor layer structure including the three sub-cells that are connected by two tunnel junctions. Each of the sub-cells within the triple junction cell 190 may react differently to short wavelength light (high-energy light) and long wavelength light (low-energy light). Short-wavelength light may cause photo carriers to be produced in the sub-cells, which diffuse within the sub-cell until they are either collected at the p-n junction or recombined with a majority carrier in bulk or at the interface. When all of the photo carriers are gathered at the junction rather than recombining elsewhere, the efficiency of the solar cell increases. Recombination affects the effectiveness of the sub-cells in the front and back of the triple junction cell 190. The window layers, emitter layers, base layers, and back surface field (BSF) layers in each sub-cell may include different doping concentrations and layer thicknesses.

The first sub-cell 120 may include a first back-surface field layer 122, a first base layer 124, a first emitter layer 126, and a first window layer 128. The first sub-cell 120 may be connected to the second sub-cell 130 with a series by tunnel diodes 185 that includes highly doped thin layers. In some embodiments, the first back-surface field layer 122 may include AlGaInP. In some embodiments, the first window layer 128 may include AlInP. The first emitter layer 126 may include GaInP. The first base layer 124 may include GaInP. Photocurrents may strongly depend on first sub-cell thickness since the air mass zero spectrum contains comparatively more high-energy photons with energy greater than the energy bandgap of the first cell 120. GaInP/GaInAs/Ge triple-junction cells have also shown efficiency under one-sun AM0 spectrum in the range of 30% for space applications.

The second sub-cell 130 may include a second back-surface field layer 132, a second base layer 134, a second emitter layer 136, and a second window layer 138. The second sub-cell 130 may be connected to the third sub-cell 140 with a series by tunnel diodes 185 that includes highly doped thin layers. In some embodiments, the second back-surface field layer 132 may include AlGaAs. In some embodiments, the second window layer 138 may include AlInP. The second emitter layer 136 may include GaInAs. The second base layer 134 may include GaInAs.

The third sub-cell 140 may include a third base layer 144, a third diffused emitter layer 146, and a third window layer 148. The third sub-cell 140 may be connected to the second sub-cell 130 with a series by tunnel diodes 185 that includes highly doped thin layers. In some embodiments, the third window layer 148 may include GaInP. The third diffused emitter layer 146 may include Ge. The third base layer 144 may include Ge.

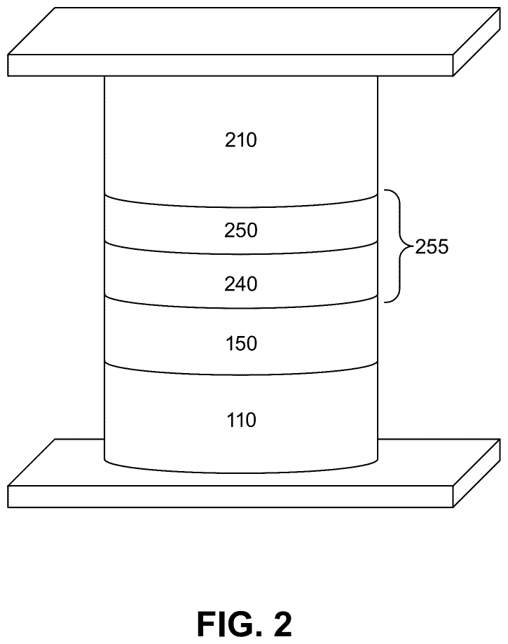

Referring to FIG. 2, illustrated is an example of a coverglass layer 210 directly bonded to the active layers 150 grown on the germanium substrate 110. Following the growth of the active layers 150, the coverglass layer 210 may be bonded to the active layers 150 via a transparent bond 255. The transparent bond 255 may be formed from the fusion of a first dielectric layer 240 and a second dielectric layer 250. In some embodiments, the first dielectric layer 240 and the second dielectric layer 250 may be formed from SiO₂. In some embodiments, the coverglass layer may be thicker than the active layers 150. The active layers 150 may be a plurality of semiconductor layers.

The coverglass layer 210 may have a very high level of transparency to maximize the solar radiation reaching the active layers 150 and to increase the efficiency of the flip-chip solar cell. The coverglass layer 210 may include sapphire. In comparison to borosilicate and other glasses having decreased transmission, the optical transmission of the coverglass layer 210 made of sapphire may be unaffected over a wide-band spectral range. Additionally, sapphire is very resistant to damage and loss of optical transparency due to radiation exposure. This is a significant advantage for coverglass in space applications. The coverglass layer 210 made of sapphire may be advantageous over other glasses due to its structural strength and high amount of relative transmission. The coverglass layer 210 may be configured to provide structural support for the active layers 150. In some embodiments, the coverglass layer 210 may be made with a borosilicate layer or borosilicate cover glass layer. Compared to other materials such as silicon, the coverglass layer 210 made of sapphire may maintain a strong structural compatibility with germanium as temperature increases. Unlike silicon, the coverglass layer 210 made of sapphire has a coefficient of thermal expansion closer to germanium than silicon. Compared to other fabrication materials (e.g., germanium and silicon), the coverglass layer 210 made of sapphire provides a very high relative transmission of radiation.

The transparent bond 255 may be formed between the active layers 150 and the coverglass layer 210 for joining the active layers 150 to the coverglass layer 210. A force may be applied to form the transparent bond 255 interposed between the active layers 150 and the coverglass layer 210. The transparent bond 255 may include the first dielectric layer 240 coupled to the active layers 150 and the second dielectric layer 250 coupled to the coverglass layer 210. The transparent bond 255 between the active layers 150 and the coverglass layer 210 may be formed by the force applied to the first dielectric layer 240 and the second dielectric layer 250 interposed between the active layers 150 and the coverglass layer 210.

The transparent bond 255 may be formed by joining the first dielectric layer 240 and the second dielectric layer 250. The transparent bond 255 may be formed between the active layers 150 and the coverglass layer 210. The transparent bond 255 may be formed by direct wafer bonding or adhesive wafer bonding. The transparent bond 255 may allow solar radiation to pass through the first dielectric layer 240 and the second dielectric layer 250 to the active layers 150. The bond formed between the two surfaces of the first dielectric layer 240 and the second dielectric layer 250 may be a covalent bond with direct wafer bonding. Initially, a weaker bond may be formed by force applied between the flat, clean surfaces of the first dielectric layer 240 and the second dielectric layer 250. Then, the covalent bond may strengthen the weaker bond between the first dielectric layer 240 and the second dielectric layer 250 through the high-temperature annealing process.

The coverglass layer 210 may be conjoined with the active layers 150 and the germanium substrate 110 via direct wafer bonding. Direct wafer bonding may join a flat, clean surface of the first dielectric layer 240 with a flat, clean surface of the second dielectric layer 250 without intermediate adhesives. Direct wafer bonding may occur as a result of chemical bonds (e.g., covalent bonds) being formed between the molecules of the first dielectric layer 240 and the second dielectric layer 250. The chemical bonds may form between the two flat, clean surfaces being brought together under force. The force may be applied to the top of the coverglass layer 210 and/or the bottom of the germanium substrate 110. The force may be simultaneously applied to the top of the coverglass layer 210 and the bottom of the germanium substrate 110. The force applied may measure at least a few kilonewtons in high vacuum 10⁻⁵ bar. The chemical bond initially formed between the two surfaces may be weak at room temperature. The maximum bond strength may be reached by transforming the weak bonds into covalent bonds through a high-temperature thermal annealing process. This thermal annealing process may be carried out to strengthen the bond between the two surfaces after the weak bond is formed. The direct wafer bonding process may create the maximum bond strength but may also require a very clean and smooth wafer.

In some embodiments, the coverglass layer 210 may be conjoined with the active layers 150 and the germanium substrate 110 via an adhesive wafer bonding. The adhesive wafer bonding may join the two surfaces of the first dielectric layer 240 and the second dielectric layer 250 with the use of intermediate adhesives. The intermediate adhesives may include a polymer, a spin-on glass, resists, and a polyimide. The adhesive may be selected based on the germanium substrate 110 materials and the topography of the coverglass layer 210 and the substrate layer. Unlike direct wafer bonding, adhesive wafer bonding may not require the high-temperature annealing process and a clean, flat surface of the first dielectric layer 240 and the second dielectric layer 250. But adhesive wafer bonding may not have as high of thermal stability over a larger temperature range as direct wafer bonding. In some embodiments, the coverglass layer 210 may be less than 200 μm thick. In some embodiments, the coverglass layer 210 may include sapphire.

The first dielectric layer 240 and the second dielectric layer 250 may be formed from SiO₂. In some embodiments, the first dielectric layer 240 and the second dielectric layer 250 may be a multi-film stack of dielectrics. The multi-film stack of dielectrics may create an anti-reflective layer to reduce the reflection loss between the coverglass layer 210 and the first sub-cell 120 with an index of refraction (n) of ˜3.3 and the sapphire wafer with n of ˜1.8. In some embodiments, the first dielectric layer 240 and the second dielectric layer 250 forms a transparent bond 255 that includes an anti-reflective layer. The anti-reflective layer in the transparent bond 255 may be configured to reduce reflection between the active layers 150 and the coverglass layer 210. The dielectric stack may include MgF2, SiO2, TiO2, Al203, Si3N4, Ta2O5, ZnO, and ZnS or other suitable materials. In some embodiments, the materials for the dielectric stack may be selected to minimize absorptive losses, have large differences in index of refraction, be mechanically stable, and available for deposition in the manufacturing facility. The number of layers in the dielectric stack and the thickness of the constituent layers will be determined through calculation of the reflectance and transmission via the transfer matrix method or other calculation.

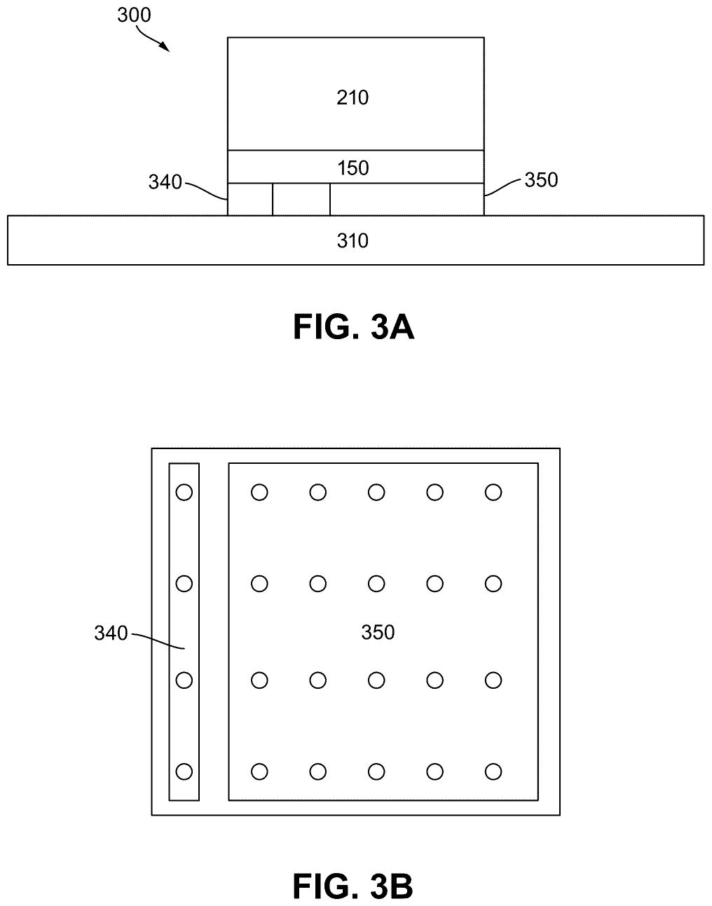

Referring to FIG. 3A, illustrated is an example of the fabricated flip-chip solar cell 300 bonded to a printed circuit board 310. The fully fabricated solar cell may include the p-type electrode pad 340 and the n-type electrode pad 350 mounted to the printed circuit board 310. The active layers 150 may be positioned above the n-type electrode pad 350 and the p-type electrode pad 340. The coverglass layer 210 may be positioned above the active layers 150 and may be configured to receive solar radiation. The second side of the active layers 150 may be configured to face the solar radiation. The p-type electrode pad 340 and the n-type electrode pad 350 may be coupled to a first side of the active layers 150 opposite the second side that receives the solar radiation. The polarity of the electrode pads may be switched such that the n-type electrode pad 350 is p-type and p-type electrode pad 340 is n-type. In addition to the pads, the polarity of the semiconductor layers are also reversed in this possible embodiment with n-type changed to p-type and p-type changed to n-type doping and conductivity.

The flip-chip solar cell 300 may be manufactured by growing the active layers 150 on top of the germanium substrate 110. Once grown, the coverglass layer 210 may be bonded to the active layers 150 with the germanium substrate 110 with the transparent bond 255. Then, the germanium substrate 110 may be removed or thinned and the p-type electrode pad 340 and the n-type electrode pad 350 may be joined to finalize the fabrication process of the flip-chip solar cell 300. The fabricated flip-chip solar cell 300 may allow solar radiation to pass through the coverglass layer 210 and the transparent bond 255 to be received at the active layers 150. The active layers 150 may be a plurality of semiconductor layers. In some embodiments, no metal layer is interposed between the active layers 150 and the coverglass layer 210.

Referring to FIG. 3B, illustrated is a bottom view of the flip-chip solar cell 300 including a p-type electrode pad 340 and the n-type electrode pad 350. The p-type electrode pad 340 and the n-type electrode pad 350 are configured to couple to the printed circuit board 310 to deliver electrical power to an external system.

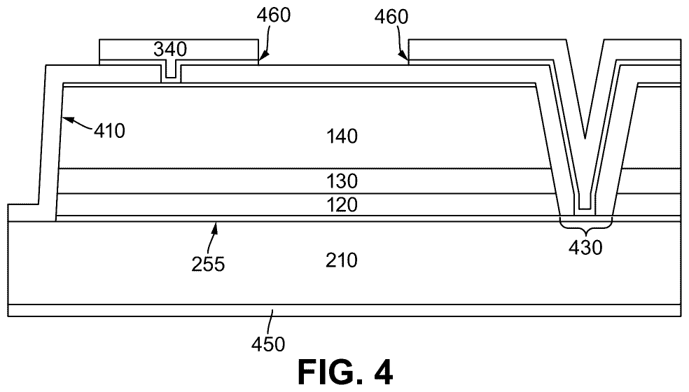

Referring to FIG. 4, illustrated is an example of a cross-section of a fabricated flip-chip solar cell 300 having a contact via 430 to a first sub-cell 120. The fabricated flip-chip solar cell 300 may include contact via 430 and a via stopping in the first sub-cell 120. The contact via 430 does not pass through all the way through the active layers 150.

The fabricated flip-chip solar cell 300 may include the first sub-cell 120, the second sub-cell 130, and the third sub-cell 140. The first sub-cell 120, the second sub-cell 130, and the third sub-cell 140 (i.e., the active layers 150) may be flipped such that the third sub-cell 140 is at the top of the stack and the first sub-cell 120 may be positioned at the bottom of the stack when assembling the flip-chip solar cell 300. The first sub-cell 120, the second sub-cell 130, and the third sub-cell 140 may be referred to as the active layers 150. The active layers 150 may be configured to convert solar radiation into electrical power. The conversion to electrical power may be accomplished by the multiple energy bandgaps across the first sub-cell 120, the second sub-cell 130, and the third sub-cell 140. The energy bandgap of the first sub-cell 120 may be greater than the second sub-cell 130. The energy bandgap of the second sub-cell 130 may be greater than the third sub-cell 140

The fabricated flip-chip solar cell 300 may include a p-contact metal 420 extending across the top of the third sub-cell 140. The p-contact metal 420 may be configured to electrically connect the p-type electrode pad 340 to the third sub-cell 140. The p-contact metal 420 may extend across the entire surface of the third sub-cell 140 to maximize the conduction between the third sub-cell 140 and the p-contact metal 420. The p-contact metal 420 may be deposited on the fabricated flip-chip solar cell 300 following the thinning of the germanium substrate 110.

A passivation layer 410 may be placed over the p-contact metal 420 and the sides of the active layers 150. The passivation layer 410 may create an insulation barrier between the n-type electrode pad 350 and the p-contact metal 420. The passivation layer 410 may be a dielectric layer that insulates the p-contact metal 420 from the n-type electrode pad 350. The passivation layer 410 may manage stress on the flip-chip solar cell 300 and prevent cracking at the active layers 150 or elsewhere. In some embodiments, the passivation layer 410 may include SiO₂ or SiN. The passivation layer 410 may have a thickness of approximately 0.2 μm to 2.0 μm thick.

The contact via 430 may be configured to electrically connect the n-type electrode pad 350 to the first sub-cell 120 via a contact metal layer 460. The contact via 430 may be formed from an etch in the active layers 150 that passes through the third sub-cell 140, the second sub-cell 130, and then partially passes through the first sub-cell 120. The contact via 430 may stop at a middle portion of the first sub-cell 120 before passing through the entire first sub-cell 120. Following the etch of the contact via 430, the passivation layer 410, the contact metal layer 460, and the n-type electrode pad 350 may be deposited in the contact via 430. The passivation layer 410 in the contact via 430 may be deposited on the sides of the contact via 430 to create an insulation barrier between the active layers 150 and the contact metal layer 460. The contact metal layer 460 may be deposited on the passivation layer 410 in the contact via 430 and be configured to electrically connect the n-type electrode pad 350 to the first sub-cell 120. The n-type electrode pad 350 may be deposited on the contact metal layer 460 in the contact via 430 to enhance conductivity and provide an improved bond to a printed-circuit board (PCB). The contact metal layer 460 may be configured to electrically couple the n-type electrode pad 350 to the first sub-cell 120. Manufacturing the contact via 430 may utilize via stopping techniques so that the contact via 430 partially passes through the second sub-cell layer. In some embodiments, the set of contact vias 430 may terminate with an ohmic metallization within the first sub-cell 120.

The anti-reflective layer 450 may be positioned on the backside of the coverglass layer 210. The anti-reflective layer 450 may be configured to increase the fraction of incident light passing into the coverglass layer 210 and reduce reflection at a surface of the coverglass layer 210. The anti-reflective layer 450 may be a dielectric stack. In some embodiments, the dielectric stack may have an index of refraction (n) of ˜3.3 and the sapphire wafer with n˜1.8. The dielectric stack may include MgF2, SiO2, TiO2, Al203, Si3N4, Ta2O5, ZnO, and ZnS or other suitable materials. In some embodiments, the materials for the dielectric stack may be selected to minimize absorptive losses, have large differences in index of refraction, be mechanically stable, and available for deposition in the manufacturing facility. The number of layers in the dielectric stack and the thickness of the constituent layers will be determined through calculation of the reflectance and transmission via the transfer matrix method or other calculations. In some embodiments, the active layers 150 may include an integrated anti-reflective layer that is configured to reduce reflection between the active layers 150 and the coverglass layer 210.

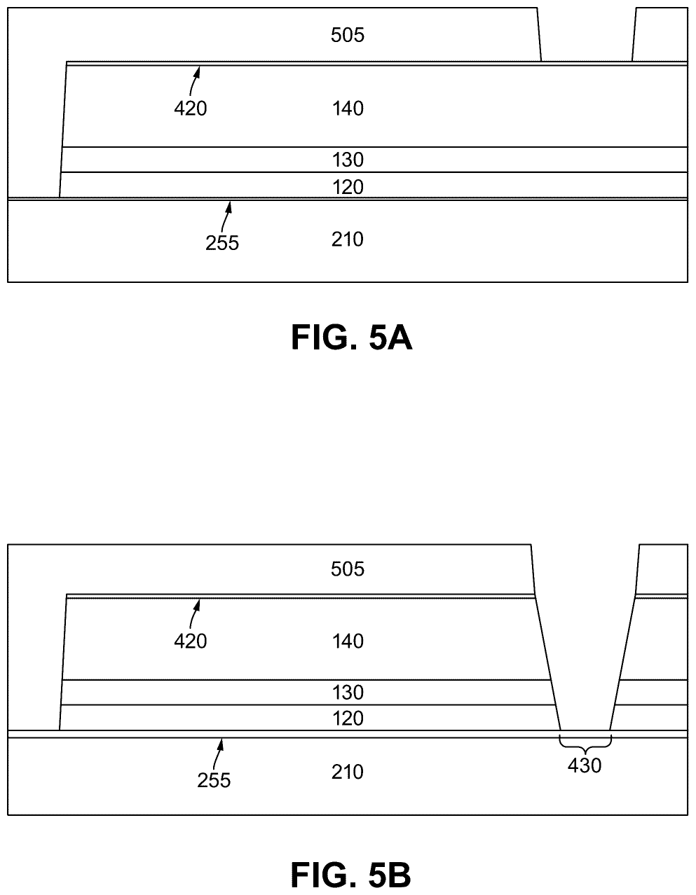

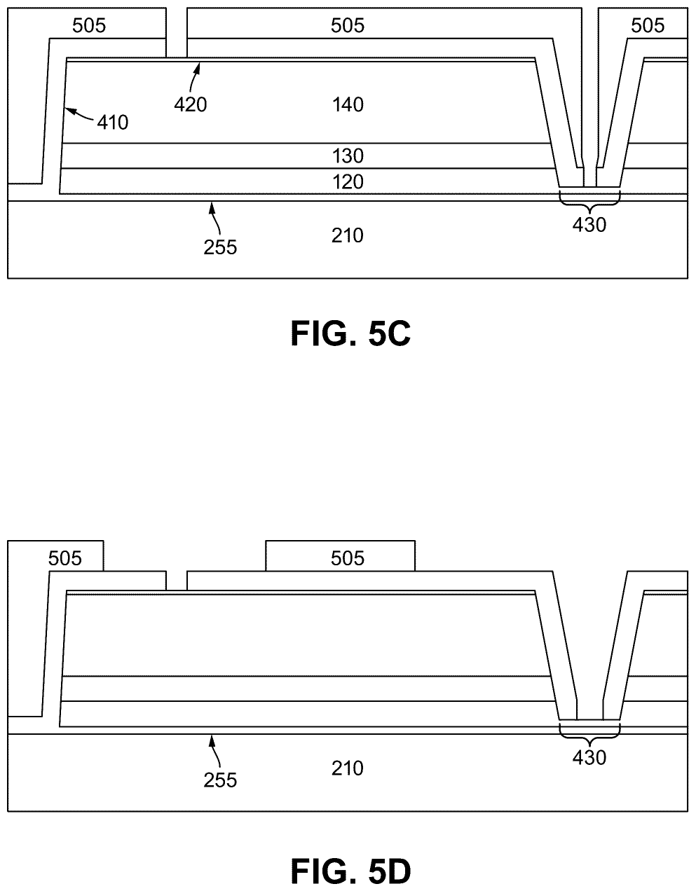

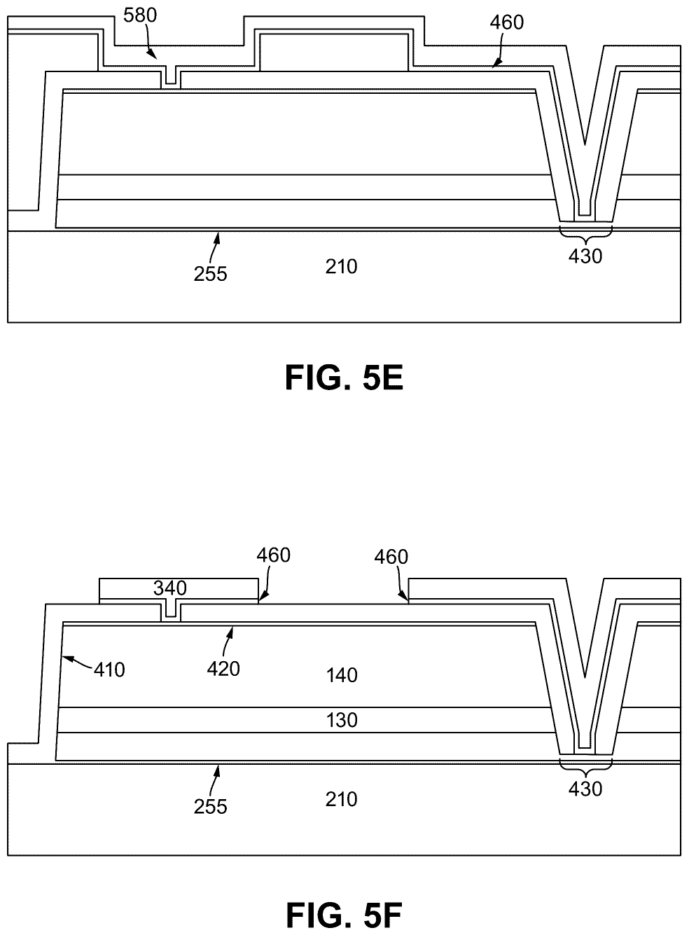

Referring to FIG. 5A, illustrated is an example of a cross-section of partially fabricated flip-chip solar cell 300 with a photoresist layer 505 deposited on the p-contact metal 420 for creating an etch for the contact via 430 to expose the first sub-cell 120. Prior to depositing the p-contact metal 420, the germanium substrate 110 may be thinned and the top surface of the third sub-cell 140 may be cleaned.

The p-contact metal 420 may be deposited on the top surface of the third sub-cell 140 of the active layers 150. The top surface of the third sub-cell 140 may be leveled and the deposition of the p-contact metal 420 may cover the entire top surface of the third sub-cell 140. The edge of the solar cell may be etched by placing a resist layer over the p-contact metal 420 and by performing a wet etch and/or dry etch. The wet etch and/or dry etch may remove the active layers 150 to expose the transparent bond 255. The photoresist layer 505 may be stripped to expose the p-contact metal 420 following the wet and/or dry etch at the active layers 150.

A photoresist layer 505 may be deposited on the p-contact metal 420 to form the contact via 430. The photoresist layer 505 may be deposited on the p-contact metal 420 in the areas where the epitaxial area is to remain in place. The photoresist layer 505 may include an aperture where the contact via 430 is to be formed.

Referring to FIG. 5B, illustrated is an example of a cross-section of a partially fabricated flip-chip solar cell 300 with an etch for the contact via 430 that passes through the third sub-cell 140, the second sub-cell 130, and partially passes through the first sub-cell 120. A combination of wet and dry etches may be used to remove the p-contact metal 420, the third sub-cell 140, and the second sub-cell 130 to expose the first sub-cell 120. A photo-etch may remove a portion of the first sub-cell 120 to form the contact via 430.

Referring to FIG. 5C, illustrated is an example of a cross-section of a partially fabricated flip-chip solar cell 300 with a passivation deposition and a photoresist layer 505 for creating an etch through the passivation layer 410 to expose the p-contact metal 420 and the first sub-cell 120.

A passivation layer 410 may be placed over the p-contact metal 420 and the sides of the active layers 150. The passivation may create an insulation barrier between the n-type electrode pad 350 and the p-contact metal 420. The passivation layer 410 may be a dielectric layer that insulates the p-contact metal 420 from the n-type electrode pad 350. The passivation layer 410 may manage stress on the flip-chip solar cell 300 and prevent cracking at the active layers 150 or elsewhere. In some embodiments, the passivation layer 410 may be SiO₂ or SiN. The passivation layer 410 may have a thickness of approximately 0.2 μm to 2.0 μm thick.

A photoresist layer 505 may be deposited on the passivation layer 410. The resist etch layer may include a first aperture and a second aperture for an etch in the passivation layer 410. In some embodiments, the first aperture may correspond to the location of p-type electrode pad 340 and the second aperture may correspond to the location of the contact via 430. The etching at the two apertures in the photoresist layer 505 may be carried out by the n-via photo-etch, a wet etch, or a dry etch to remove the passivation layer 410. The photoresist layer 505 may be stripped to expose the passivation layer 410 following the etch at the two apertures.

Referring to FIG. 5D, illustrated is an example of a cross-section of a partially fabricated solar cell with a liftoff photoresist layer 505 for creating the n-type electrode pad 350 and the p-type electrode pad 340. Following the etch in the passivation layer 410 and stripping the photoresist layer 505, a new liftoff photoresist layer 505 may be deposited on the passivation layer 410 in which the openings in the passivation layer 410 correspond to the n-type electrode pad 350 and the p-type electrode pad 340.

Following the deposition of the liftoff photoresist layer 505, a contact metal layer 460 may be deposited on the passivation layer 410 and the liftoff photoresist layer 505. The contact metal layer 460 creates a conductive pathway between the p-contact metal 420 to the p-type electrode pad 340. Additionally, the contact metal layer 460 may create a conductive pathway between the first sub-cell 120 and the n-type electrode pad 350. The contact metal layer 460 forming the conductive pathway between the first sub-cell 120 and the n-type electrode pad 350 may be the n-contact metal.

Referring to FIG. 5E, illustrated is an example of a cross-section of a partially fabricated flip-chip solar cell 300 with a metal contact deposition and an electrode pad deposition formed over the two etches and the liftoff photoresist layer 505. Following the deposition of the contact metal layer 460, the electrode pad layer 580 may be deposited on the contact metal layer 460. The electrode pad layer 580 may be a different metal than the contact metal layer 460. The metal forming the electrode pad layer 580 may be configured to attach the cell to a PCB. In some embodiments, the electrode pad layer 580 may be formed of gold or a gold-tin alloy.

Referring to FIG. 5F, illustrated is an example of a cross-section of a partially fabricated flip-chip solar cell 300 of an n-type electrode pad 350 and a p-type electrode pad 340 that are formed by a lift-off of the liftoff photoresist layer 505. Following the deposition of the electrode pad layer 580, a lift-off strip of the liftoff photoresist layer 505 may be performed to leave the p-type electrode pad 340 and the n-type electrode pad 350. The passivation layer 410 may be exposed between the p-type electrode pad 340 and the n-type electrode pad 350. The polarity of the electrode pads may be switched such that the n-type electrode pad 350 is p-type and p-type electrode pad 340 is n-type. In addition to the pads, the polarity of the semiconductor layers is also reversed in this possible embodiment with n-type changed to p-type and p-type changed to n-type doping and conductivity.

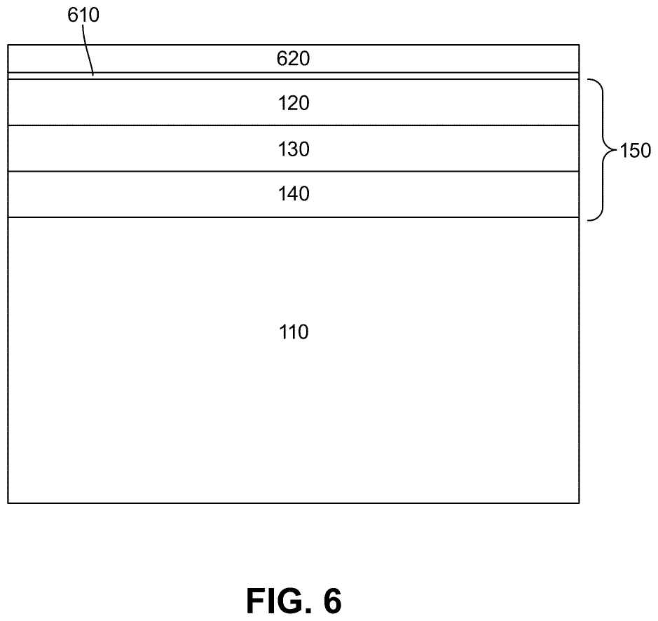

Referring to FIG. 6, illustrated is an example of a transparent conductive layer 610 deposited on active layers 150 with a germanium substrate 110. The transparent conductive layer may be deposited on the first sub-cell 120 of the active layers 150 to provide current spreading and ohmic contact. The transparent conductive layer 610 may be a continuous plane deposited on the first sub-cell 120 of the active layers 150. The transparent conductive layer may be an indium tin oxide layer or an indium zinc oxide layer over the first sub-cell 120 or AlInP layer. In some embodiments, no metal layer may be interposed between the active layers 150 and the coverglass layer 210. In some embodiments, the coverglass layer may be thicker than the active layers 150. The coverglass layer 210 may be configured to provide structural support for the active layers 150. The active layers 150 may be a plurality of semiconductor layers.

In some embodiments, the transparent conductive layer 610 may be deposited on the side of the active layers 150 that receives the solar radiation. The transparent conductive layer 610 may be an indium tin oxide layer deposited on the active layers 150. The indium tin oxide layer may have a thickness ranging from 30 to 1000 nm. The indium tin oxide layer may be sputtered and annealed. The indium tin oxide layer may create an ohmic contact and a current spreading effect. The thickness of the indium tin oxide layer may be reduced to decrease absorption losses. The number of through-vias may be inversely proportional to the thickness of the indium tin oxide layer. For example, fewer through-vias require a thicker indium tin oxide layer. In another example, a thinner indium tin oxide layer may require more through-vias. The first sub-cell 120 of the active layers 150 may be configured to face the solar radiation. The p-type electrode pad 340 and the n-type electrode pad 350 may be coupled to a side of the active layers 150 opposite the side that receives the solar radiation.

In some embodiments, an oxide bonding layer 620 may be deposited on the transparent conductive layer 610. The oxide bonding layer 620 may be formed between the active layers 150 and the coverglass layer 210. The oxide bonding layer 620 may prevent peeling between the coverglass layer 210 and the transparent conductive layer 610. In some embodiments, an adhesion is applied between the oxide bonding layer 620 to prevent the peeling between the oxide bonding layer 620 and the transparent conductive layer 610 in case the oxide bonding layer 620 does not stick well to the indium tin oxide layer. The oxide bonding layer 620 may be a dielectric, such as SiO₂. In some embodiments, the adhesion between the oxide bonding layer 620 and the transparent conductive layer 610 may include Al₂O₃ or TiON to create a thin, transparent layer in the range of approximately 10 angstroms to 100 angstroms. Following the deposition of the oxide bonding layer 620, the coverglass layer 210 may be bonded via the direct wafer bonding. In some embodiments, no metal layer is interposed between the active layers 150 and the coverglass layer 210.

Uniformity problems may exist when constructing a contact via 430 that partially passes through the first sub-cell 120. For example, non-uniform thickness of the active layers 150 and imprecision in the etching processes may cause the etch process to pass through the entirety of the first sub-cell 120. The transparent conductive layer 610 may solve these problems by allowing a through-via 710 to be constructed instead of a contact via 430. The transparent conductive layer 610 allows for a through-via 710 to be constructed, connecting the n-type electrode pad 350 to the first sub-cell 120. The transparent conductive layer 610 may be created using an end-point detection to stop the etch when the active layers 150 are removed to expose the transparent conductive layer 610. In some embodiments, the transparent conductive layer 610 may be created with a wet etch that etches through the active layers 150 until reaching the transparent conductive layer 610. The transparent conductive layer 610 may solve problems related to contact via 430 partially passing through the first sub-cell 120 by spreading the current and maintaining the series resistance low.

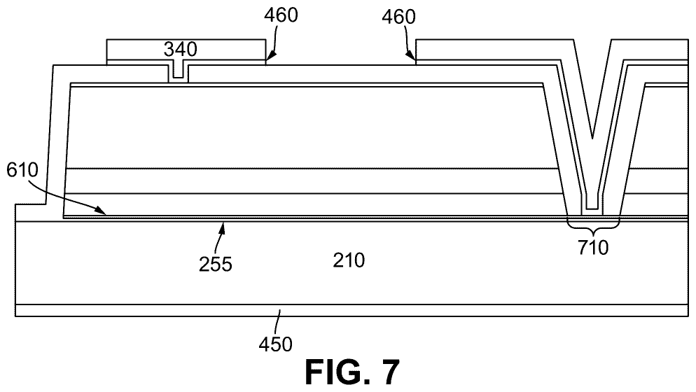

Referring to FIG. 7, illustrated is an example of a cross-section of a fabricated solar cell having a through-via 710 to a transparent conductive layer 610. The fabricated flip-chip solar cell 300 may include a through-via 710 that passes through the entire epitaxial layer for connecting to the transparent conductive layer 610. By including the transparent conductive layer 610, a through-via 710 may be etched through the active layers 150 using end-point detection to stop the etch when the active layers 150 are removed to expose the transparent conductive layer 610. Additionally, and/or alternatively, a wet etch may remove the active layers 150 to expose the transparent conductive layer 610. The through-via 710 can be created without requiring the precision of etching through a portion of the first sub-cell 120 of the active layers 150.

The fabricated flip-chip solar cell 300 may include the first sub-cell 120, the second sub-cell 130, and the third sub-cell 140. The first sub-cell 120, the second sub-cell 130, and the third sub-cell 140 (i.e., the active layers 150) may be flipped such that the third sub-cell 140 is at the top of the stack and the first sub-cell 120 may be positioned at the bottom of the stack when assembling the flip-chip solar cell 300. The first sub-cell 120, the second sub-cell 130, and the third sub-cell 140 may be referred to as the active layers 150. The active layers 150 may be configured to convert the solar radiation into electrical power. The conversion to electrical power may be accomplished by the multiple bandgaps across the first sub-cell 120, the second sub-cell 130, and the third sub-cell 140.

The fabricated flip-chip solar cell 300 may include a p-contact metal 420 extending across the top of the third sub-cell 140. The p-contact metal 420 may be configured to electrically connect the p-type electrode pad 340 to the third sub-cell 140. The p-contact metal 420 may extend across the entire surface of the third sub-cell 140 to maximize the conduction between the third sub-cell 140 and the p-contact metal 420. The p-contact metal 420 may be deposited on the fabricated flip-chip solar cell 300 following the thinning of the germanium substrate 110.

A passivation layer 410 may be placed over the p-contact metal 420 and the sides of the active layers 150. The passivation layer 410 may create an insulation barrier between the n-type electrode pad 350 and the p-contact metal 420. The passivation layer 410 may be a dielectric layer that insulates the p-contact metal 420 from the n-type electrode pad 350. The passivation layer 410 may manage stress on the flip-chip solar cell 300 and to prevent cracking at the active layers 150 or elsewhere. In some embodiments, the passivation layer 410 may include SiO₂ or SiN. The passivation layer 410 may have a thickness of approximately 0.2 μm to 2.0 μm thick.

The through-via 710 may be configured to electrically connect the n-type electrode pad 350 to the transparent conductive layer 610 via a contact metal layer 460. The through-via 710 may be formed from an etch in the active layers 150 that passes through the first sub-cell 120, the second sub-cell 130, and the third sub-cell 140 to expose the transparent conductive layer 610. Following the etch of the through-via 710, the fabrication process may dispose the passivation layer 410, the contact metal layer 460, and the n-type electrode pad 350. The passivation layer 410 in the through-via 710 may be deposited on the sides of the through-via 710 to create an insulation barrier between the active layers 150 and the contact metal layer 460. The contact metal layer 460 may be deposited on the passivation layer 410 in the through-via 710 and electrically connect the n-type electrode pad 350 to the transparent conductive layer 610. The n-type electrode pad 350 may be deposited on the contact metal layer 460 in the through-via 710 to enhance conductivity and reinforce the contact metal layer 460 deposited in the through-via 710. The contact metal layer 460 may be configured to electrically couple the n-type electrode pad 350 to the transparent conductive layer 610.

The transparent conductive layer 610 may be transparent to solar radiation, conductive, and configured to minimize the series resistance. The transparent conductive layer 610 may be configured to make ohmic contact with the first sub-cell 120 of the active layers 150. The transparent conductive layer 610 may be resistant to changes under thermal cycling and solar exposure. The transparent conductive layer 610 may be an indium tin oxide layer or an indium zinc oxide layer over the first sub-cell 120 or InGaP layer. In some embodiments, the indium tin oxide layer has a higher energy absorption edge than the indium zinc oxide layer, allowing more high-energy photons to pass through.

The oxide bonding layer 620 may be formed from a dielectric, such as SiO₂. In some embodiments, the oxide bonding layer 620 may be formed from two dielectric layers pressed together under a force. In some embodiments, the oxide bonding layer 620 may be a multi-film stack of dielectrics. The multi-film stack of dielectrics may have the effect of an anti-reflective layer to reduce the reflection loss between the coverglass layer 210 and the first sub-cell 120 with an index of refraction (n) of ˜3.3 and the sapphire wafer with n˜1.8. The dielectric stack may include MgF2, SiO2, TiO2, Al203, Si3N4, Ta2O5, ZnO, and ZnS or other suitable materials. In some embodiments, the materials for the dielectric stack may be selected to minimize absorptive losses, have large differences in index of refraction, be mechanically stable, and available for deposition in the manufacturing facility. The number of layers in the dielectric stack and the thickness of the constituent layers will be determined through calculation of the reflectance and transmission via the transfer matrix method or other calculations. In some embodiments, the active layers 150 may include an integrated anti-reflective layer that is configured to reduce reflection between the active layers 150 and the coverglass layer 210.

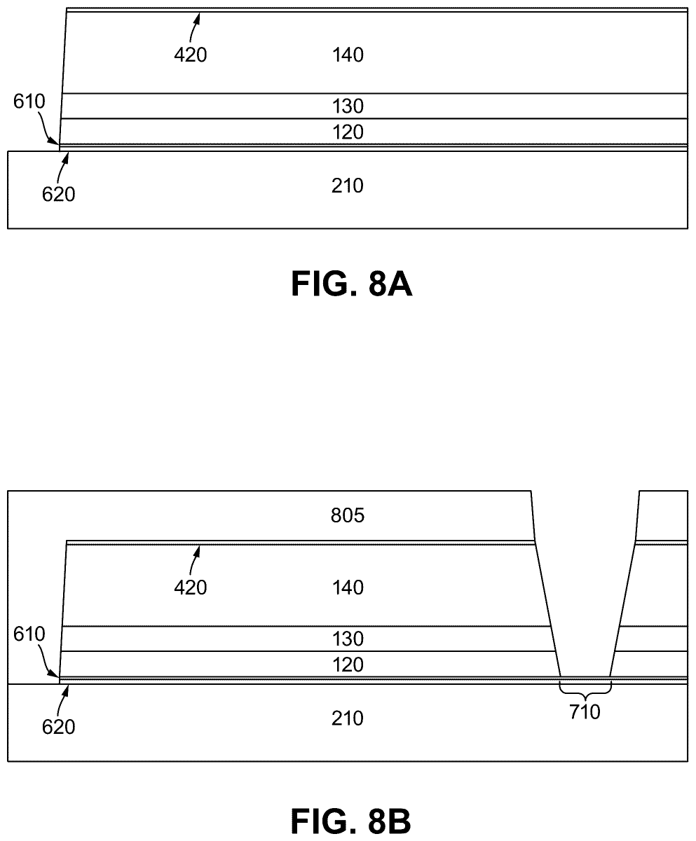

Referring to FIG. 8A, illustrated is an example of a cross-section of a partially fabricated flip-chip solar cell 300 with a p-metal contact deposited on the active layers 150 and an etch at the edge of the solar cell passing through the transparent conductive layer 610 and the oxide bonding layer 620.

The p-contact metal 420 may be deposited on the top surface of the third sub-cell 140 of the active layers 150. The top surface of the third sub-cell 140 may be leveled and the p-contact metal 420 may cover the entire top surface of the third sub-cell 140. The edge of the flip-chip solar cell 300 may be etched by placing a resist layer 805 over the p-contact metal 420 and performing a wet and/or dry etch. The wet and/or dry etch may remove the active layers 150, the transparent conductive layer 610, and the oxide bonding layer until the coverglass layer 210 is exposed. The transparent conductive layer 610 may be removed to prevent a conductive material from extending to the edge of the flip-chip solar cell 300. The resist layer 805 may be stripped to expose the p-contact metal 420 following the wet or dry etch at the active layers 150.

Referring to FIG. 8B, illustrated is an example of a cross-section of a partially fabricated flip-chip solar cell 300 with an etch for the through-via 710 that passes through the first sub-cell 120, the second sub-cell 130, and the third sub-cell 140 layer to expose the transparent conductive layer 610. A resist layer 805 may be deposited on the p-contact metal 420 to form the through-via 710. The resist layer 805 may be deposited on the p-contact metal 420 in the areas where the epitaxial area is to remain. An aperture in the resist layer 805 may be positioned where the through-via 710 is to be formed. A combination of wet and dry etches may be used to remove the p-contact metal 420, the first sub-cell 120, the second sub-cell 130, and the third sub-cell 140 to expose the transparent conductive layer 610. An etch may remove a portion of the first sub-cell 120 to form the through-via 710.

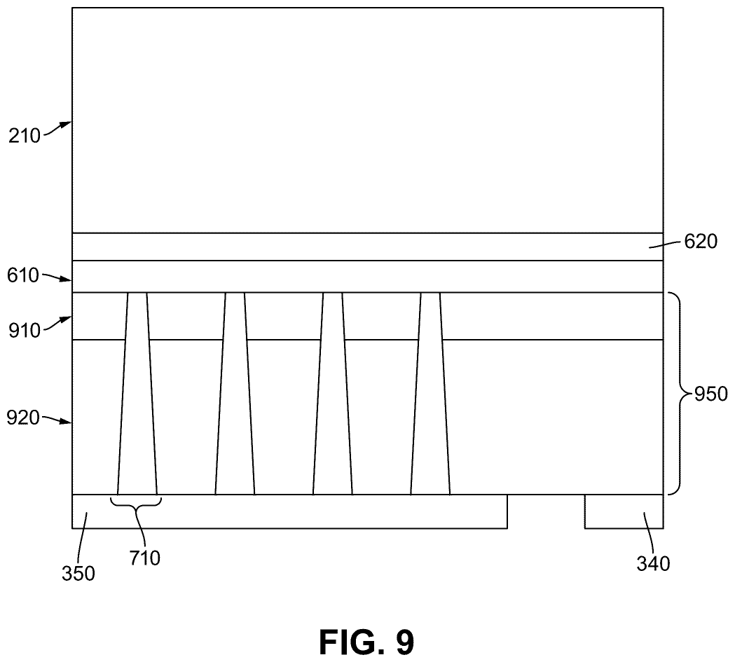

Referring to FIG. 9, illustrated is a fabricated flip-chip solar cell with a silicon semiconductor layer having a first doped region and a second doped region. The silicon semiconductor layer 950 may be doped by diffusing a dopant in the semiconductor layer to create a first doped region 910 and a second doped region 920. To achieve high quantum efficiency, the flip-chip solar cell 300 may include n-doped regions and p-doped regions with a very small concentration of material defects. Material defects provide recombination sites for photo-generated charge carriers.

The silicon semiconductor layer 950 may include through-vias 710 passing through the silicon semiconductor layer 950 to establish an electrical connection between the transparent conductive layer 610 and the n-type electrode pad 350. In some embodiments, no metal layer is interposed between the active layers 150 and the coverglass layer 210.

The silicon semiconductor layer 950 may have a first doped region 910 at a first side of the silicon semiconductor layer 950 and a second doped region 920 at a second side of the silicon semiconductor layer 950. The silicon semiconductor layer 950 may be configured to convert solar radiation to electrical energy. The second side of the silicon semiconductor layer 950 may be configured to face the solar radiation. The first doped region 910 may be an n-type region and the second doped region 920 may be a p-type region. Similarly, the first doped region 910 may be a p-type region and the second doped region 920 may be an n-type region. In some embodiments, the transparent conductive layer 610 may be deposited on the side of the active layers 150 that receives the solar radiation.

The fabricated flip-chip solar cell may include an n-type electrode pad 350 and a p-type electrode pad 340. The n-type electrode pad 350 and the p-type electrode pad 340 may be coupled to the first side to the silicon semiconductor layer 950. The n-type electrode pad 350 may be electrically connected to a transparent conductive layer 610 with a plurality of through-vias 710. The transparent conductive layer 610 may be electrically connected to the first doped region 910 (e.g., the n-type region). The transparent conductive layer 610 may be a continuous plane deposited on the first doped region 910. The through-vias 710 may pass through the entire silicon semiconductor layer 950, including the first doped region 910 and the second doped region 920, to establish an electrical connection between the n-type electrode pad 350 and the transparent conductive layer 610. The through-vias 710 may taper between the n-type electrode pad 350 and the transparent conductive layer 610. The p-type electrode pad 340 may be electrically connected to the second doped region 920 (e.g., the p-type region) via direct contact or a metal layer interposed between the second doped region 920 and the p-type electrode pad 340. The first doped region 910 of the silicon semiconductor layer 950 may be configured to face the solar radiation. The p-type electrode pad 340 and the n-type electrode pad 350 may be coupled to a side of the silicon semiconductor layer 950 opposite the side that receives the solar radiation.

The through-vias 710 may be configured to electrically connect the n-type electrode pad 350 to the transparent conductive layer 610. The through-via 710 may be formed from an etch in the silicon semiconductor layer 950 that passes through the first doped region 910 and the second doped region 920 to expose the transparent conductive layer 610. The through-vias 710 may be an electrical conduit between the first doped region 910 and the n-type electrode pad 350. In some embodiments, no metal layer is interposed between the active layers 150 and the coverglass layer 210.

The coverglass layer 210 may be coupled to the second side of the silicon semiconductor layer 950 via an oxide bonding layer 620. The oxide bonding layer 620 may be a dielectric, such as SiO₂. In some embodiments, the adhesion between the oxide bonding layer 620 and the transparent conductive layer 610 may include AlO₃ or TiON to create a thin, transparent layer in the range of approximately 10 angstroms to 100 angstroms. Following the deposition of the oxide bonding layer 620, the coverglass layer 210 may be bonded via the direct wafer bonding. The coverglass layer 210 may be configured to pass the solar radiation to the silicon semiconductor layer 950 and provide structural support for the silicon semiconductor layer 950. In some embodiments, no metal layer is interposed between the silicon semiconductor layer 950 and the coverglass layer 210. The coverglass layer 210 may be configured to provide structural support for the silicon semiconductor layer 950.

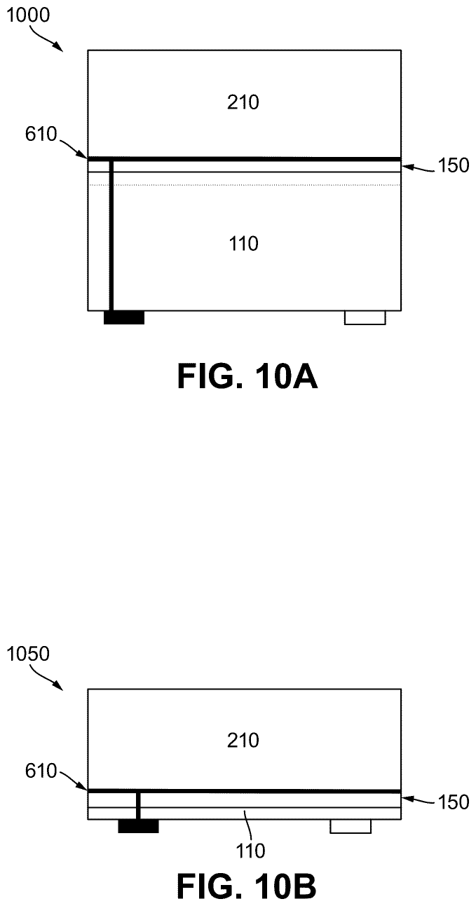

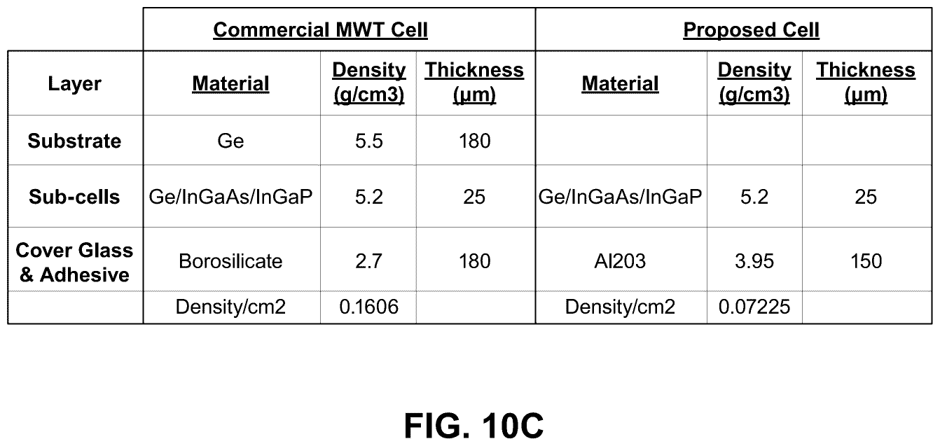

Referring to FIG. 10A, illustrated is a diagram of a commercial metal-wrap-through solar cell. The current solar cell diagram 1000 may have a coverglass layer 210, active layers 150, and a germanium substrate 110. The coverglass layer 210 may have a thickness of approximately 180 μm. The active layers 150 may have a thickness of approximately 25 μm. The germanium substrate 110 may have a thickness of approximately 180 μm.

Referring to FIG. 10B, illustrated is a proposed solar cell diagram of the layer thicknesses of the fabricated flip-chip solar cell 300 with the thinned-down germanium layer and the thinned-down coverglass layer 210 (sapphire in this embodiment) for weight reduction. The proposed solar cell diagram 1050 may have a coverglass layer 210, active layers 150, and a germanium substrate 110.

The germanium substrate 110 may be thinned down to optimize the optical absorption and current matching to the other layers. The germanium substrate 110 may be thinned from a thickness of approximately 200 μm to a thickness of approximately 20 μm. The germanium substrate 110 may be approximately twice as dense as silicon. Rather than thinning, the substrate may be cleaved or removed by another method that leaves it intact, then the removed germanium substrate 110 may grow additional active layers 150 for another flip-chip solar cell 300. The removed germanium substrate 110 may be denser than coverglass layer 210. Removing the germanium substrate 110 may remove more weight from the flip-chip solar cell 300 than the same amount of coverglass layer 210. Removing the germanium substrate 110 from the flip-chip solar cell 300 may reduce the overall weight of the flip-chip solar cell 300.

The coverglass layer 210 may be thinned to a thickness of approximately 100-200 μm. In some embodiments, the coverglass layer 210 may both protect the active layers 150 and serve as a structural reinforcement. In some embodiments, the coverglass layer 210 may replace the cover glass. Replacing the cover glass with the coverglass layer 210 may reduce the weight of the flip-chip solar cell 300. The final thickness of the coverglass layer 210 may depend on the stress in the build. As the germanium substrate 110 is made thinner, the built-in stress of the stack may cause the wafers to warp. In some embodiments, the thickness of the coverglass layer 210 may be selected to withstand handling and prevent damage to the fabricated flip-chip solar cell 300. In some embodiments, the coverglass layer 210 may have a thickness of 150 μm.

Referring to FIG. 10C, illustrated is a solar cell comparison table 1090 comparing the thickness and density of the proposed flip-chip solar cell 300 to the current flip-chip solar cell. For the current cell, the cover glass and the adhesive may have a thickness of approximately 180 μm. The active layers 150 may have a thickness of approximately 25 μm. The germanium substrate 110 may have a thickness of approximately 180 μm. The overall density of the current cell may be 0.1606 g/cm³.

For the proposed cell, the germanium substrate 110 may be thinned from a thickness of approximately 200 μm to a thickness of approximately 20 μm or less. In some embodiments, the coverglass layer 210 may replace the germanium substrate 110 for mechanical support and have a thickness of 150 μm. The active layers 150 may have a thickness of approximately 25 μm. In some embodiments, the cover glass and the adhesive may be removed. In some embodiments, the flip-chip solar cell 300 may have a mass per area is <0.1 g/cm³. The overall density of the proposed cell may be 0.07225 g/cm³. Removing the germanium substrate 110 from the flip-chip solar cell 300 may reduce the overall weight of the flip-chip solar cell 300.

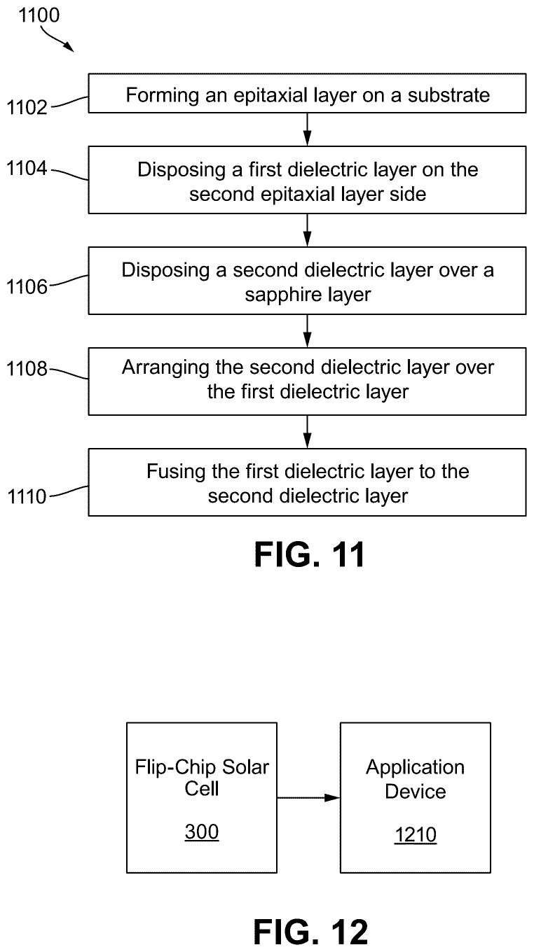

Referring to FIG. 11, illustrated is a flip-chip solar cell 300 fabrication flowchart 1100 for bonding a coverglass layer 210 to an active layers 150 with a germanium substrate 110.

At 1102, the active layers 150 are formed on a germanium substrate 110. The active layers 150 may have a third sub-cell 140 at a first side and a first sub-cell 120 at a second side, the first side opposing the second side and coupled to the germanium substrate 110. The active layers 150 may be configured to convert solar radiation to electrical energy. The active layers 150 may be a plurality of semiconductor layers.

At 1104, a first dielectric layer 240 is deposited on the second side of the epitaxial layer. Following the growth of the active layers 150, the coverglass layer 210 may be bonded to the active layers 150 via a transparent bond 255. The transparent bond 255 may be formed from the fusion of a first dielectric layer 240 and a second dielectric layer 250. In some embodiments, the first dielectric layer 240 and the second dielectric layer 250 may be formed from SiO₂.

At 1106, a second dielectric layer 250 is deposited on a coverglass layer 210. The coverglass layer 210 may have a very high level of transparency to maximize the solar radiation reaching the active layers 150 and to increase the efficiency of the flip-chip solar cell 300. The coverglass layer 210 made of sapphire may be advantageous over other glasses due to its structural strength and robustness against radiation damage. In some embodiments, the coverglass layer 210 may be a borosilicate glass.

At 1108, a second dielectric layer 250 is arranged over the first dielectric layer 240. Fabricating the flip-chip solar cell includes forming an epitaxial layer configured to convert solar radiation to electrical energy on a substrate. Forming the flip-chip solar cell may include disposing a first dielectric layer on a second side. Forming the flip-chip solar cell may include disposing a second dielectric layer over the coverglass layer 210. The coverglass layer 210 may be configured to receive the solar radiation to be converted to electrical power. Forming the flip-chip solar cell may include arranging the second dielectric layer over the first dielectric layer such that the coverglass layer 210 and the epitaxial layer are positioned on opposing sides of the first dielectric layer and the second dielectric layer. Forming the flip-chip solar cell may include fusing the first dielectric layer to the second dielectric layer via a transparent bond.

At 1110, the first dielectric layer 240 is fused to the second dielectric layer 250. The coverglass layer 210 may be conjoined with the active layers 150 and the germanium substrate 110 via direct wafer bonding. Direct wafer bonding may join a flat, clean surface of the first dielectric layer 240 with a flat, clean surface of the second dielectric layer 250 without intermediate adhesives. Direct wafer bonding may occur as a result of chemical bonds (e.g., covalent bonds) being formed between the molecules of the first dielectric layer 240 and the second dielectric layer 250. The chemical bonds may form between the two flat, clean surfaces being brought together under force. The force may be applied to the top of the coverglass layer 210 and/or the bottom of the germanium substrate 110. The force may be simultaneously applied to the top of the coverglass layer 210 and the bottom of the germanium substrate 110.

Now referring to FIG. 12, illustrated is a block diagram of the flip-chip solar cell device coupled to an application device. The flip-chip solar cell 300 may be coupled to an application device 1210 or any of a wide variety of devices or systems for providing electric power to such devices and systems. The flip-chip solar cell 300 may be configured to directly or indirectly provide electric power to the application device 1210. The flip-chip solar cell 300 can be externally coupled to the application device 1210, or it may be incorporated as part of the application device 1210. The application device 1210 may include a battery charging system, an electronic device, a climate control system, a portable power system, a stationary power system, a backup power device, and/or an environmental sensor, as described in some non-limiting examples below. The flip-chip solar cell 300 may be configured to power a non-terrestrial application device coupled to the flip-chip solar cell 300.

In an implementation, the flip-chip solar cell 300 may be configured for powering an electrically powered vehicle, an electrically powered boat, an electrically powered aircraft, and/or the like. The battery charging system may be configured to support a power source (e.g., a battery) for increasing electric energy storage or extending a range of a vehicle.

In another implementation, the flip-chip solar cell 300 may be configured to generate power in an electronic device. In some embodiments, the electronic device may include a computer, a processor, a memory, a sensor, a wireless range extender, a cellular device, a mobile device, a watch, a tablet, a wearable electronic device, a medical device (e.g., a pacemaker, a hearing aid, an implantable sensor), an IoT device, and/or the like. The energy conversion device may be configured to generate power in an electronic system. In some embodiments, the electronic system may include a communication network, a cellular communication system, and/or the like. In some embodiments, a first edge of the flip-chip solar cell 300 is within 0.5 mm of a second edge of a second surface-mountable solar cell.

In another implementation, the flip-chip solar cell 300 may be configured to generate power in a portable power system. In some embodiments, the portable power system may include a high-reliability all-weather power system, a high-reliability, noise-free power system, a self-powered lighting system, a heat pump, a heat pump for satellites or space vehicles, and/or the like. In some embodiments, the flip-chip solar cell 300 and the second flip-chip solar cell cover more than 75% of a module surface area of the non-terrestrial application device.

In another implementation, the flip-chip solar cell 300 may be configured to generate power for a backup power device. In some embodiments, the backup power device may include a communication system failsafe device, a smoke detector failsafe device, a carbon monoxide detector failsafe device, and a toxic gas sensor failsafe device configured to detect hydrofluoric acid, boron trifluoride, phosphoryl chloride, methane, and/or the like. In another implementation, the flip-chip solar cell 300 may be configured to generate power for an environmental sensor. In some embodiments, the environmental sensor may be a sensor buoy device, a microelectromechanical system (MEMS) device, a remote device, and/or the like.

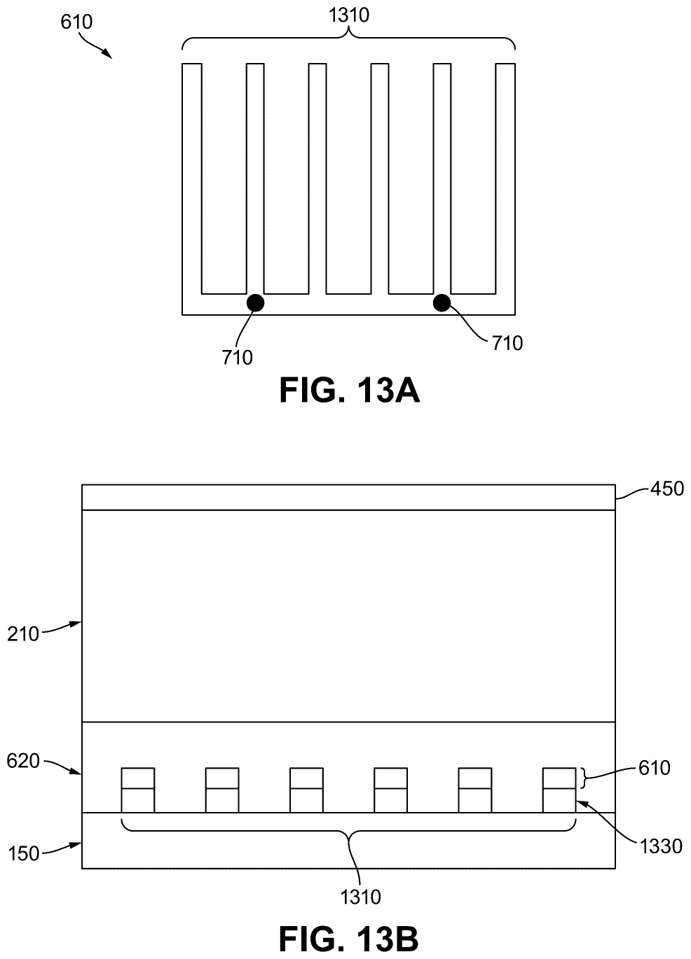

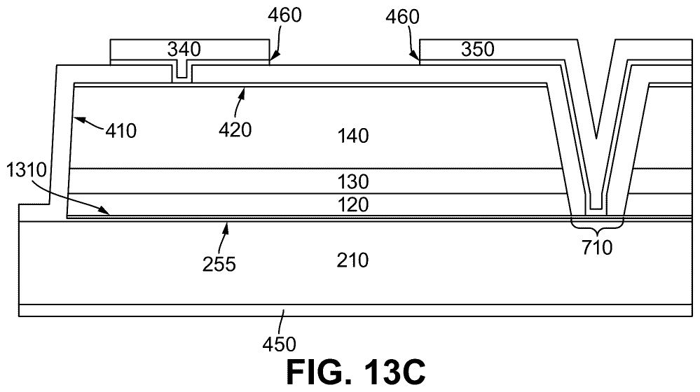

Now referring to FIG. 13A, illustrated is a top-view of an example of a transparent conductive layer 610 having finger contacts 1310 extending from one end of the transparent conductive layer 610. The transparent conductive layer 610 with finger contacts 1310 may be implemented on GaInP/GaInAs/Ge triple-junction cells.

The transparent conductive layer 610 may absorb solar radiation having shorter wavelengths or can block the radiation from reaching the active layers 150. Absorbing and/or blocking the solar radiation may decrease the output and efficiency of the fabricated flip-chip solar cell 300. To increase the power output and efficiency of the fabricated flip-chip solar cell 300, the transparent conductive layer 610 may have a planar surface area smaller than the planar surface area of the layers below the transparent conductive layer 610. For example, the transparent conductive layer 610 may have a planar surface area smaller than the planar surface area of the active layers 150. The smaller planar surface area of the transparent conductive layer 610 may expose the underlying active layers 150. The exposed underlying active layers 150 may receive the solar radiation unimpeded by the transparent conductive layer 610 by passing through gaps at the transparent conductive layer 610.

Several architectures of the transparent conductive layer 610 may be implemented to minimize the planar surface area. In some embodiments, the transparent conductive layer 610 may have finger contacts 1310 that extend from one side of the transparent conductive layer 610. These finger contacts 1310 may be contact lines configured to have ohmic contact with the underlying layer (e.g., the active layers 150). The finger contacts 1310 of the transparent conductive layer 610 may be electrically connected and may extend in the same direction from one side of the transparent conductive layer 610. In some embodiments, the finger contacts 1310 may extend from a common line or a bus bar at the one side of the transparent conductive layer 610. The common line of the bus bar may be electrically connected to one or more through-vias 710. The finger contacts 1310 may be configured to have a spacing between each other to allow radiation to pass through to the active layers 150 below. In some embodiments, the finger contacts 1310 may be evenly spaced from one another in a uniform pattern across the transparent conductive layer 610. The finger contacts 1310 may extend from the one side of the transparent conductive layer 610 to the opposite side of the transparent conductive layer 610. In some embodiments, the one side of the transparent conductive layer 610 may be aligned with a first edge of the active layer 150 and the opposite side of the transparent conductive layer 610 having the finger contacts 1310 may be aligned with a second edge of the active layer 150 opposite the first edge of the active layer 150.

The transparent conductive layer 610 may have a non-uniform coverage over the active layer 150 to increase to pass-through radiation reaching the active layer 150. To prevent the absorption of shorter frequencies by the transparent conductive layer 610, the architecture of the transparent conductive layer 610 may be designed to minimize the footprint of the transparent conductive oxide over the active layers 150.

Now referring to FIG. 13B, illustrated is a cross-section of an example of a transparent conductive layer 610 having finger contacts 1310 deposited on active layers 150 of a GaInP/GaInAs/Ge triple-junction cell. An oxide bonding layer 620 may be deposited on the transparent conductive layer 610 with finger contacts 1310. The oxide bonding layer 620 may be formed between the active layers 150 and the coverglass layer 210. The transparent conductive layer 610 with finger contacts 1310 may be implemented on GaInP/GaInAs/Ge triple-junction cells. In some embodiments, an anti-reflective layer 450 may be positioned on the backside of the coverglass layer 210. The anti-reflective layer 450 may be configured to reduce reflection between the coverglass layer 210 and an external environment, such as air, vacuum, or another medium.

The finger contacts 1310 may extend from one side of the transparent conductive layer 610 to the opposite side of the transparent conductive layer 610 in one direction. The finger contacts 1310 may create an ohmic contact with the active layers 150 below with an epitaxial layer 1330. The finger contacts 1310 may be configured to have a spacing between each other to allow radiation to pass through to the layers below. For example, the finger contacts 1310 may be spaced apart to allow solar radiation to reach the active layers 150. The oxide bonding layer 620, a dielectric material, and/or an anti-reflective coating may fill the spacing between the finger contacts 1310.

The finger contacts 1310 of the transparent conductive layer 610 may be disposed on an epitaxial layer 1330. The epitaxial layer 1330 may have the same footprint as the finger contacts 1310 of the transparent conductive layer 610. The epitaxial layer 1330 may have the same footprint as the finger contacts 1310 of the transparent conductive layer 610. In some embodiments, the footprint of the epitaxial layer 1330 may be restricted to the footprint of the transparent conductive layer 610. The epitaxial layer 1330 may absorb a portion of the spectrum of the solar radiation. The footprint of the epitaxial layer 1330 may be minimized when the epitaxial layer 1330 absorbs the at least a portion of the spectrum of radiation and, as such, prevents radiation from reaching the active layers 150. The epitaxial layer 1330 may be configured to be disposed on the active layers 150.

The epitaxial layer 1330 may be used to create an ohmic contact between the finger contacts 1310 and the active layers 150. Similar to the finger contacts 1310, the epitaxial layer 1330 may extend from one side of the transparent conductive layer 610 to the opposite side of the transparent conductive layer 610 in one direction. The epitaxial layer 1330 may be etched to have the same footprint as the finger contacts 1310. In some embodiments, the epitaxial layer 1330 may be a low-bandgap epitaxial layer such as gallium arsenide. In some embodiments, the epitaxial layer 1330 may be a low-bandgap epitaxial layer such as InGaAs.

In some embodiments, an oxide bonding layer 620 may be deposited between and on the finger contacts 1310. The oxide bonding layer 620 may be a dielectric layer, such as SiO₂. In some embodiments, the oxide bonding layer 620 may include an integrated anti-reflective layer. In some embodiments, the adhesion between the oxide bonding layer 620 and the transparent conductive layer 610 may include Al₂O₃ or TiON to create a thin, transparent layer. Following the deposition of the oxide bonding layer 620, the coverglass layer 210 may be bonded via the direct wafer bonding. In some embodiments, no metal layer is interposed between the active layers 150 and the coverglass layer 210. The oxide bonding layer 620 may be formed between the active layers 150 and the coverglass layer 210.

Referring to FIG. 13C, illustrated is an example of a cross-section of a fabricated solar cell 300 having a finger contact 1310 of a transparent conductive layer 610. The fabricated flip-chip solar cell 300 may include a through-via 710 that passes through the entire epitaxial layer for connecting to the transparent conductive layer 610 with finger contacts 1310. By including the transparent conductive layer 610 with finger contacts 1310, a through-via 710 may be etched through the active layers 150 using end-point detection to stop the etch when the active layers 150 are removed to expose the transparent conductive layer 610. The fabricated solar cell 300 may have at least one finger contact 1310 passing through the fabricated solar cell 300.

The through-via 710 may be configured to electrically connect the n-type electrode pad 350 to the transparent conductive layer 610 via a contact metal layer 460. The through-via 710 may be formed from an etch in the active layers 150 that passes through the first sub-cell 120, the second sub-cell 130, and the third sub-cell 140 to expose the transparent conductive layer 610 with finger contacts 1310. The contact metal layer 460 may be deposited on the passivation layer 410 in the through-via 710 and electrically connect the n-type electrode pad 350 to the transparent conductive layer 610 with finger contacts 1310. The n-type electrode pad 350 may be deposited on the contact metal layer 460 in the through-via 710 to enhance conductivity and reinforce the contact metal layer 460 deposited in the through-via 710. The contact metal layer 460 may be configured to electrically couple the n-type electrode pad 350 to the transparent conductive layer 610 with finger contacts 1310.

The transparent conductive layer 610 may be conductive and configured to minimize the series resistance. The transparent conductive layer 610 with finger contacts 1310 may be configured to make ohmic contact with the first sub-cell 120 of the active layers 150. The transparent conductive layer 610 with finger contacts 1310 may be resistant to changes under thermal cycling and solar exposure. The transparent conductive layer 610 with finger contacts 1310 may be an indium tin oxide layer or an indium zinc oxide layer over the first sub-cell 120 or InGaP layer.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” may be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

The many features and advantages of the disclosure are apparent from the detailed specification, and thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and accordingly, all suitable modifications and equivalents may be resorted to, falling within the scope of the disclosure.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The implementations set forth in the foregoing description do not represent all implementations consistent with the subject matter described herein. Instead, they are merely some examples consistent with aspects related to the described subject matter. Although a few variations have been described in detail herein, other modifications or additions are possible. In particular, further features and/or variations can be provided in addition to those set forth herein. For example, the implementations described above can be directed to various combinations and sub-combinations of the disclosed features and/or combinations and sub-combinations of one or more features further to those disclosed herein. In addition, the logic flows depicted in the accompanying figures and/or described herein do not necessarily require the particular order shown, or sequential order, to achieve desirable results. The scope of the following claims may include other implementations or embodiments.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

While the foregoing is directed to implementations of the present disclosure, other and further implementations of the disclosure may be devised without departing from the basic scope thereof, and the scope thereof is determined by the claims that follow.

What is claimed is:

1. A surface-mountable solar cell comprising:
a plurality of semiconductor layers having a first side and a second side, the first side opposing the second side, the plurality of semiconductor layers configured to convert solar radiation to electrical energy, the second side configured to face the solar radiation;
a coverglass layer coupled to the second side via a bond, the coverglass layer being configured to pass the solar radiation to the plurality of semiconductor layers and provide structural support for the plurality of semiconductor layers; and
a first electrode pad and a second electrode pad coupled to the first side and electrically coupled to the plurality of semiconductor layers,
wherein the coverglass layer is thicker than the plurality of semiconductor layers, and
wherein no metal layer is interposed between the plurality of semiconductor layers and the coverglass layer.

2. The surface-mountable solar cell of claim 1, wherein the plurality of semiconductor layers includes sub-cells including at least first sub-cell, a second sub-cell, and a third sub-cell, the first sub-cell having a first energy bandgap, the second sub-cell having a second energy bandgap, and the third sub-cell having a third energy bandgap, the first energy bandgap being greater than the second energy bandgap and the third energy bandgap.

3. The surface-mountable solar cell of claim 2, wherein the plurality of semiconductor layers includes at least one of Ge, In, Al, Ga, As, P, N, Si, or Sb.

4. The surface-mountable solar cell of claim 2, wherein the first sub-cell is electrically coupled to at least one of the first electrode pad or the second electrode pad by a set of contact vias that partially pass through the first sub-cell, the set of contact vias terminating with an ohmic metallization within the first sub-cell.

5. The surface-mountable solar cell of claim 2, wherein the first sub-cell is electrically coupled to at least one of the first electrode pad or the second electrode pad by a set of through vias that pass through the first sub-cell, the set of through vias being coupled to a transparent conductive layer interposed between the plurality of semiconductor layers and the coverglass layer.

6. The surface-mountable solar cell of claim 5, wherein the transparent conductive layer is deposited on the second side of the plurality of semiconductor layers, and wherein the transparent conductive layer has fingers extending across the second side of the plurality of semiconductor layers.

7. The surface-mountable solar cell of claim 1, wherein the bond between the second side of the plurality of semiconductor layers and the coverglass layer is formed by a force applied to a dielectric layer interposed between the second side of the plurality of semiconductor layers and the coverglass layer.

8. The surface-mountable solar cell of claim 7, wherein the dielectric layer includes a first dielectric layer portion coupled to the second side of the plurality of semiconductor layers and a second dielectric layer portion coupled to the coverglass layer, and wherein the bond between the second side of the plurality of semiconductor layers and the coverglass layer is formed by the force applied to the first dielectric layer portion and the second dielectric layer portion interposed between the second side of the plurality of semiconductor layers and the coverglass layer.

9. The surface-mountable solar cell of claim 1, wherein the coverglass layer is less than 200 μm thick.

10. The surface-mountable solar cell of claim 1, wherein the coverglass layer includes sapphire.

11. The surface-mountable solar cell of claim 1, further comprising:
a contact metal layer extending across the first side of the plurality of semiconductor layers, the contact metal layer configured to electrically couple to at least one of the first electrode pad or the second electrode pad.

12. The surface-mountable solar cell of claim 1, wherein the surface-mountable solar cell has a mass per area is <0.1 g/cm³.

13. The surface-mountable solar cell of claim 1, further comprising:
an anti-reflective layer interposed between the plurality of semiconductor layers and the coverglass layer, the anti-reflective layer configured to minimize reflection between the plurality of semiconductor layers and the coverglass layer.

14. The surface-mountable solar cell of claim 13, wherein the anti-reflective layer includes a stack of dielectric layers and wherein the anti-reflective layer is further configured to reduce reflection of incident light passing through the coverglass layer.

15. The surface-mountable solar cell of claim 1, wherein an anti-reflective layer is deposited on the coverglass layer, the anti-reflective layer configured to minimize reflection at the coverglass layer.

16. The surface-mountable solar cell of claim 15, wherein the anti-reflective layer includes a stack of dielectric layers and wherein the anti-reflective layer is further configured to reduce reflection of incident light at a surface of the coverglass layer.

17. A surface-mountable solar cell comprising:
a plurality of semiconductor layers having a first side and a second side, the first side opposing the second side, the plurality of semiconductor layers configured to convert solar radiation to electrical energy;
a coverglass layer coupled to the second side via a bond, the coverglass layer configured to pass the solar radiation to the plurality of semiconductor layers and provide structural support for the plurality of semiconductor layers; and
a first electrode pad and a second electrode pad coupled to the first side and electrically coupled to the plurality of semiconductor layers,
wherein the coverglass layer is thicker than the plurality of semiconductor layers,
wherein no metal layer is interposed between the plurality of semiconductor layers and the coverglass layer, and
wherein the surface-mountable solar cell is configured to power a non-terrestrial application device coupled to the surface-mountable solar cell.

18. The surface-mountable solar cell of claim 17, wherein the surface-mountable solar cell forms an array with a second surface-mountable solar cell, and wherein a first edge of the surface-mountable solar cell is within 0.5 mm of a second edge of the second surface-mountable solar cell.

19. The surface-mountable solar cell of claim 18, wherein the surface-mountable solar cell and the second surface-mountable solar cell cover more than 75% of a module surface area of the non-terrestrial application device.

20. A surface-mountable solar cell comprising:
a semiconductor layer having a first doped region at a first side of the semiconductor layer and a second doped region at a second side of the semiconductor layer, the first side opposing the second side, the semiconductor layer configured to convert solar radiation to electrical energy, the second side configured to face the solar radiation;
a coverglass layer coupled to the second side via a bond, the coverglass layer configured to pass the solar radiation to the semiconductor layer and provide structural support for the semiconductor layer; and
a first electrode pad and a second electrode pad coupled to the first side and electrically coupled to the semiconductor layer,
wherein no metal layer is interposed between the semiconductor layer and the coverglass layer.
